(19) United States
(12) Patent Application Publication
(10) Pub. No.: US 2007/0069744 A1
(43) Pub. Date: Mar. 29, 2007

(54) Board for probe card, inspection apparatus, photo-fabrication apparatus and photo-fabrication method

(76) Inventors: Yasuyuki Koyagi, Kyoto (JP); Hiroko Shimozuma, Kyoto (JP); Takayoshi Tanabe, Tokyo (JP); Takao Yashiro, Tokyo (JP)

Correspondence Address: MCDERMOTT WILL & EMERY LLP, 600 13TH STREET, N.W., WASHINGTON, DC, 20005-3096, US

(21) Appl. No.: 10/557,714

(22) PCT Filed: May 10, 2004
(86) PCT No.: PCT/JP04/06569

§ 371 Date: Nov. 22, 2005

(30) Foreign Application Priority Data
May 29, 2003 (JP) 2003-151992

(51) Int. Cl. G01R 31/02

(52) U.S. Cl. 324/754

(57) ABSTRACT

A photo-fabrication apparatus (1) has a stage (2) for holding a base board (9) thereon, a feeding part (3) for feeding photosensitive material onto the base board (9), a layer forming part (4) for smoothly spreading the fed photosensitive material to form a material layer and a light emitting part (5) for emitting a spatially-modulated light beam onto the material layer. The photo-fabrication apparatus (1) forms a lot of elastic microstructures for fine probe and arranges the microstructures at microscopic intervals in a very small range with high positional accuracy on the base board (9) by repeating formation of a material layer and light emission. The microstructures become elastic probes through plating in a later process.

### TECHNICAL FIELD

The present invention relates to a technique for manufacturing a probe card used for an electrical inspection of an electric circuit and an inspection apparatus using the probe card.

### BACKGROUND ART

For an electrical inspection of electric circuits of semiconductor chips, substrates used for liquid crystal displays or the like, conventionally, a probe card has been used, which inputs a signal and detects an output signal by bringing probes into contact with electrode pads of an electric circuit. In a general-type probe card provided are a lot of cantilever-type probes extending in a slanting direction from a main body of the probe card. When there are a lot of electrode pads in a unit area to be inspected, a probe card in which tips of probes are concentrated on a very small region is used.

When an insulating film such as an oxide film is present on an electrode pad in an electric circuit, sometimes a technique is used in which a tip of a probe pressed against the electrode pad is shifted to scrape off a surface of the electrode pad and continuity between the probe and the electrode pad is thereby established.

On the other hand, as a probe card not having cantilever-type probes, proposed is a probe card using bumps which is obtained by growing nickel plating as probes, as disclosed in Japanese Patent Application Laid Open Gazette No. 9-5355.

In a probe card, it is necessary to arrange a lot of fine probes at microscopic intervals in a very small range. In recent, with high definition of objects to be inspected, since the number of probes to be needed in a unit area increases and higher positional accuracy for the probes is required, it becomes difficult to perform an inspection or the cost for an inspection apparatus becomes higher if a conventional cantilever-type probe card is used.

Further, when the number of probes increases, in a case of the probe card shown in the Japanese Patent Application Laid Open Gazette No. 9-5355, a large pressing force is needed to surely establish continuity between a lot of probes and electrode pads and this possibly produces an effect on performance of an electric circuit to be inspected.

### DISCLOSURE OF INVENTION

The present invention is intended for a board for probe card used for an electrical inspection of an electric circuit. The board for probe card comprises a base board, and three-dimensional structures each having a plurality of blocks piled up on the base board, the plurality of blocks being formed of photosensitive material.

In the board for probe card of the present invention, it is possible to easily provide a lot of three-dimensional structures for probe each of which has the piled-up blocks of photosensitive material.

According to an aspect of the present invention, in the board for probe card, each of the three-dimensional structures comprises a flexible part which bends to allow a portion farthest away from the base board to be moved toward the base board. With the probe card manufactured by using the board for probe card, it is possible to surely establish a contact between an object to be inspected and probes.

Preferably, the three-dimensional structure comprises a plurality of protruding parts which protrude from the base board, and a connecting part for connecting tips of the plurality of protruding parts. Further preferably, the plurality of protruding parts protrude from three portions which are nonlinearly arranged on the base board.

According to the present invention, the further processed board for probe card further comprises a conductive film for coating each of the three-dimensional structures. Preferably, the conductive film is a metal coating film formed by electroless plating.

The present invention is also intended for an inspection apparatus for performing an electrical inspection of an electric circuit. The inspection apparatus comprises a probe card on which probes are provided, a pressing mechanism for pressing the probes toward an electric circuit to be inspected, and an inspection part for electrically inspecting the electric circuit through the probes, and in the inspection apparatus, the probe card comprises a base board, three-dimensional structures each having a plurality of blocks formed of photosensitive material and piled up on the base board, and conductive films for coating the three-dimensional structures, respectively.

By using the inspection apparatus of the present invention, it is possible to surely establish a contact between a lot of probes and an electric circuit by using microscopic three-dimensional structures with a small pressing force. Further, since the probe card in which a lot of probes are arranged with high precision is obtained by using photosensitive material, the inspection apparatus is suitable especially for inspection of a fine electric circuit.

The present invention is further intended for a photo-fabrication apparatus for forming three-dimensional structures for probes used for an electrical inspection of an electric circuit. The photo-fabrication apparatus comprises a holding part for holding a base board, a feeding part for feeding liquid photosensitive material onto the base board, a squeegee for forming a layer of photosensitive material which is fed onto the base board on an existing layer and pushing redundant photosensitive material out into a region outside the existing layer through movement relative to the base board in a predetermined direction along a main surface of the base board, a moving mechanism for moving the squeegee relatively to the base board in the predetermined direction, a spacing change mechanism for changing a spacing between the squeegee and the holding part, and a light emitting part for emitting light to a region which is determined in advance with respect to a layer of photosensitive material formed through movement of the squeegee.

With the photo-fabrication apparatus of the present invention, it is possible to easily form a lot of three-dimensional structures for probe. Further, since the redundant photosensitive material is pushed out into a region outside the existing layer, it is not necessary to provide any resin bath and it is thereby possible to ensure size reduction of the photo-fabrication apparatus.

Preferably, the layer of photosensitive material has a thickness of 20 μm or less. Further preferably, the light emitting part comprises a spatial light modulator for generating a spatially-modulated light beam. It is therefore possible to perform light emission at high speed with high accuracy.

According to an aspect of the present invention, the photo-fabrication apparatus further comprises a control part for controlling the quantity of light to be emitted to each microscopic region on a layer of photosensitive material, and the control part comprises a storage part for storing shape data of a three-dimensional structure formed on a board and a table substantially indicating a relation between the quantity of light to be emitted onto a microscopic region on a layer of photosensitive material and a depth of exposure of the layer, and an operation part for obtaining the quantity of light to be emitted for each microscopic region on each layer of photosensitive material piled up to form the three-dimensional structure on the basis of the shape data and the table.

It is thereby possible to form a three-dimensional structure having a smooth shape.

The present invention is still further intended for a photo-fabrication method for forming three-dimensional structures for probes used for an electrical inspection of an electric circuit. The photo-fabrication method comprises a feeding step for feeding liquid photosensitive material onto a base board, a layer formation step for forming a layer of the photosensitive material on the base board by moving a squeegee relatively to the base board in a predetermined direction along a main surface of the base board, a light emitting step for emitting light to a region which is determined in advance with respect to the layer of photosensitive material, and a repeating step for repeating the feeding step, the layer formation step and the light emitting step a plurality of times, and in the photo-fabrication method, the layer of photosensitive material is formed on an existing layer and redundant photosensitive material is pushed out into a region outside the existing layer in the layer formation step included in the repeating step.

In the photo-fabrication method of the present invention, it is not necessary to provide any resin bath since the redundant photosensitive material is pushed out into a region outside the existing layer.

These and other objects, features, aspects and advantages of the present invention will become more apparent from the following detailed description of the present invention when taken in conjunction with the accompanying drawings.

### BRIEF DESCRIPTION OF DRAWINGS

FIG. 1 is a view showing a construction of a photo-fabrication apparatus in accordance with a first preferred embodiment;

FIG. 2 is a view showing a DMD,

FIG. 3 is a plan view showing part of an irradiation region;

FIG. 4 is a flowchart showing an operation flow of formation of microstructures;

FIGS. 5A to 5D are views showing formation of a material layer(s);

FIGS. 6A to 6F are views showing formation of a microstructure;

FIGS. 7A to 7F are views showing formation of a microstructure with gray-scale control;

FIGS. 8A to 8D are views showing a plating operation for the microstructures;

FIG. 9 is a flowchart showing an operation flow of plating for the microstructures;

FIG. 10 is a view showing an inspection apparatus and an electric circuit;

FIG. 11 is an enlarged view showing probes pressed against the electric circuit;

FIG. 12 is a view showing another example of microstructure;

FIG. 13 is a view showing a construction of a photo-fabrication apparatus in accordance with a second preferred embodiment;

FIG. 14 is a view showing still another example of microstructure; and

FIGS. 15A and 15B are views showing yet another example of microstructure.

### BEST MODE FOR CARRYING OUT THE INVENTION

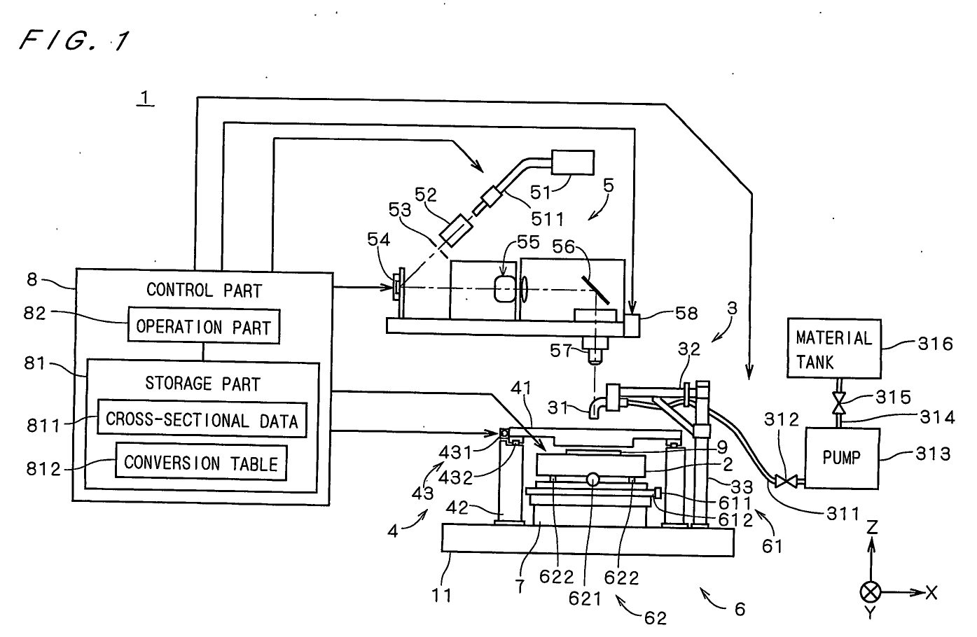

FIG. 1 is a view showing a construction of a photo-fabrication apparatus 1 in accordance with the first preferred embodiment of the present invention.

The photo-fabrication apparatus 1 is an apparatus for forming three-dimensional microstructures for probe used for an electrical inspection of an electric circuit. The photo-fabrication apparatus 1 has a base 11 which is horizontally disposed, a stage 2 for holding a base board 9 which is a base for a board for probe card, a feeding part 3 for feeding photosensitive material, i.e., liquid photocurable resin, onto the base board 9, a layer forming part 4 for forming a layer having a predetermined thickness by smoothly spreading the photosensitive material fed on the base board 9, a light emitting part 5 for emitting a light beam to the layer of photosensitive material formed on the base board 9, a stage moving mechanism 6 for moving the stage 2 relatively to the light emitting part 5, a stage up-and-down moving mechanism 7 for vertically moving the stage 2 and a camera 58 for picking up an image of an alignment mark on the base board 9.

The feeding part 3, the layer forming part 4, the light emitting part 5, stage moving mechanism 6, stage up-and-down moving mechanism 7 and the camera 58 are connected to a control part 8, and the control part 8 controls these constituent elements to form microstructures for probe on the base board 9. The control part 8 has a storage part 81 for storing a variety of data and an operation part 82 for performing a variety of arithmetic operations.

The feeding part 3 has a nozzle 31 for dropping the photosensitive material onto the base board 9 for feeding, an arm 32 for supporting the nozzle 31 at a position higher than that of the stage 2 and a column 33 vertically provided on the base 11, for supporting the arm 32 horizontally with respect to the base 11. The arm 32 is rotatably supported at an upper portion of the column 33 and the nozzle 31 is attached to a tip of the arm 32. When the arm 32 is rotated by a not-shown motor, the nozzle 31 becomes movable between a position above the base board 9 and a position away from the base board 9.

The nozzle 31 is connected to a pump 313 through a pipe 311 and a valve 312, and the pump 313 is connected to a material tank 316 through a pipe 314 and a valve 315. The control part 8 controls the pump 313 and the valves 312 and 315 to feed a predetermined amount of photosensitive material onto the base board 9 from the nozzle 31.

The layer forming part 4 has a plate-like squeegee 41 provided orthogonally to a main surface of the base board 9 (and elongating in an X direction of FIG. 1), a squeegee supporting part 42 for supporting the squeegee 41 with a lower end of the squeegee 41 (an edge adjacent to the main surface of the base board 9) kept in parallel to the main surface of the base board 9 and a squeegee moving part 43 for moving the squeegee 41 relatively to the base board 9 in a Y direction of FIG. 1. The squeegee moving part 43 moves the squeegee 41 along its guide rails 432 with a ball screw mechanism driven by a motor 431.

The light emitting part 5 has a light source 51 provided with a semiconductor laser for emitting light (having a wavelength of, e.g., approximate 300 or 400 nm) and a micromirror array 54 (e.g., a DMD (Digital micromirror device), and hereinafter, referred to as a “DMD 54”) in which a plurality of micromirrors are two-dimensionally arranged, and a light beam from the light source 51 is spatially modulated by the DMD 54 and emitted onto the base board 9.

Specifically, a light beam emitted from optical fiber bundle 511 connected to the light source 51 is guided by an optical system 52 to the DMD 54 through a shutter 53. In the DMD 54, a light beam formed of only light reflected on some of the micromirrors which have a predetermined orientation (the orientation corresponding to an ON state in the following discussion on light emission by the DMD 54) is led out. The light beam from the DMD 54 is guided to a mirror 56 through a group of lenses 55 and the light beam reflected on the mirror 56 is guided by an objective lens 57 to the base board 9.

The stage moving mechanism 6 has an X-direction moving mechanism 61 for moving the stage 2 in the X direction and a Y-direction moving mechanism 62 for moving the stage 2 in the Y direction. The X-direction moving mechanism 61 has a motor 611, guide rails 612 and a ball screw (not shown), and with rotation of the ball screw by the motor 611, the Y-direction moving mechanism 62 moves along the guide rails 612 in the X direction. The Y-direction moving mechanism 62 has the same constitution as the X-direction moving mechanism 61, and with rotation of a ball screw (not shown) by a motor 621, the stage 2 is moved along guide rails 622 in the Y direction. Further, the stage moving mechanism 6 is supported by the stage up-and-down moving mechanism 7 on the base 11, and when the stage up-and-down moving mechanism 7 is driven, the stage 2 is moved in a Z direction and a spacing between the squeegee 41 and the stage 2 is changed.

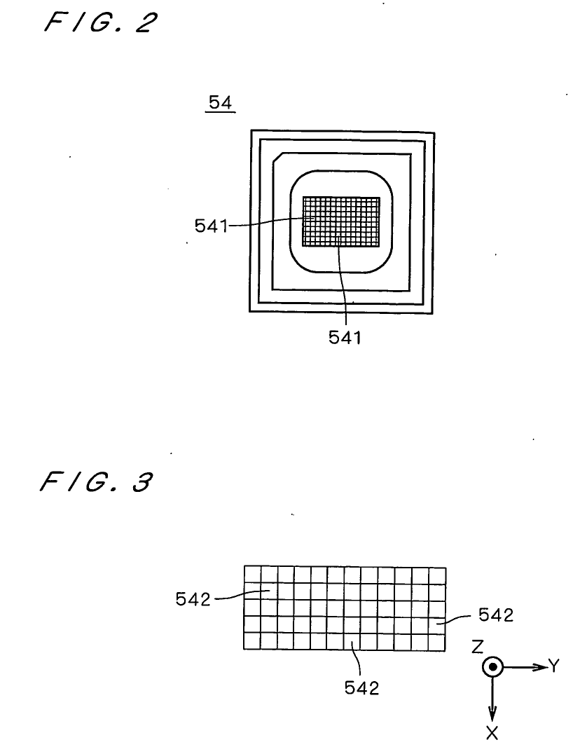

FIG. 2 is a view showing the DMD 54. The DMD 54 is a spatial light modulator in which a lot of micromirrors 541 are arranged at regular intervals in two directions orthogonal to each other (in column and row directions), and in response to input of a reset pulse in accordance with data written in memory cells corresponding to the micromirrors 541, some of the micromirrors 541 are inclined a predetermined angle by an electrostatic field effect.

FIG. 3 is a plan view showing part of an irradiation region on the base board 9 (or a layer of photosensitive material formed on the base board 9, which is discussed later). Microscopic irradiation regions (hereinafter, referred to as “microscopic regions”) 542 on the base board 9 corresponding to the micromirrors 541 each have a square shape like the micromirrors 541 and are arranged at regular intervals with a predetermined pitch, correspondingly to the micromirrors 541, in the X and Y directions of FIG. 3.

In controlling the DMD 54, data (hereinafter, referred to as “cell data”) indicating ON or OFF for each micromirror 541 is transmitted to the DMD 54 from the control part 8 of FIG. 1 and written in the corresponding memory cell in the DMD 54, and the orientation of the micromirror 541 is changed into that indicating the ON state or the OFF state in synchronization with the reset pulse in accordance with the cell data. A light microbeam emitted to each of the micromirrors 541 in the DMD 54 is thereby reflected in accordance with the direction in which the micromirror 541 is inclined to make a switching between ON and OFF of emission of light to the microscopic region 542 on the base board 9 corresponding to the micromirror 541.

In other words, a light microbeam incident on a micromirror 541 which is brought into the ON state is reflected to the group of lenses 55 and guided to a corresponding microscopic region 542 on the base board 9. A light microbeam incident on a micromirror 541 which is brought into the OFF state is reflected to a predetermined position different from the group of lenses 55 and not guided to a corresponding microscopic region 542 on the base board 9.

In the photo-fabrication apparatus 1, by controlling the DMD 54, it is possible to change the quantity of light to be emitted for each microscopic region 542. Specifically, the control part 8 transmits a reset pulse to the DMD 54 a predetermined times during a given time period to accurately control the number of ON states of each micromirror 541 (which corresponds to a cumulative time where the micromirror 541 is in the ON state), and thus the quantity of light to be emitted to each microscopic region 542 is controlled (in other words, a gray-scale (or multi-level) control is performed). It is not necessary, however, to generate the reset pulse at regular intervals, and for example, a unit time is divided into time frames of 1:2:4:8:16 and a reset pulse is transmitted one time at an initial point of each time frame, and thus a gray-scale control (in the above case, into 32 levels) is performed.

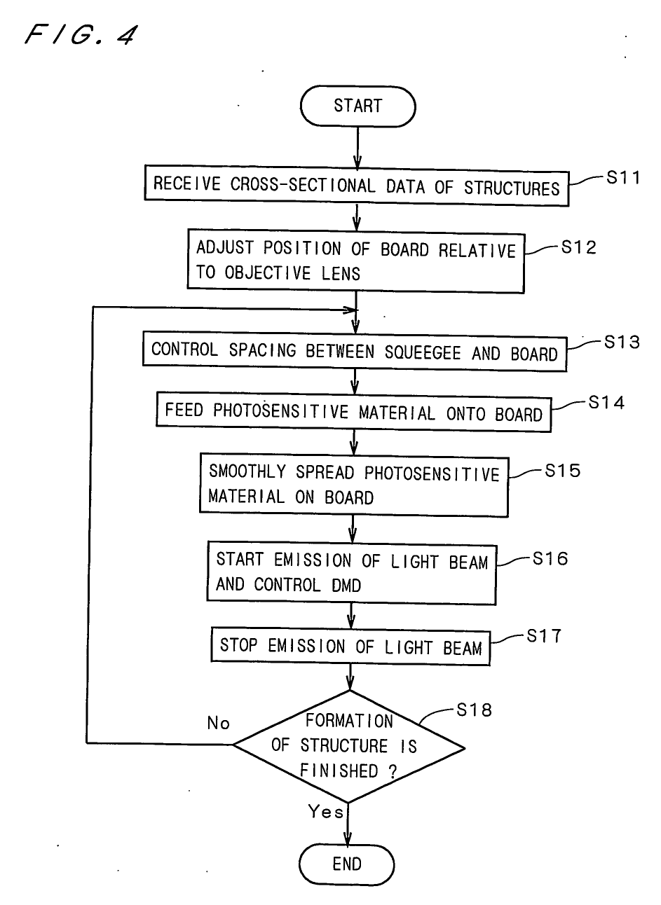

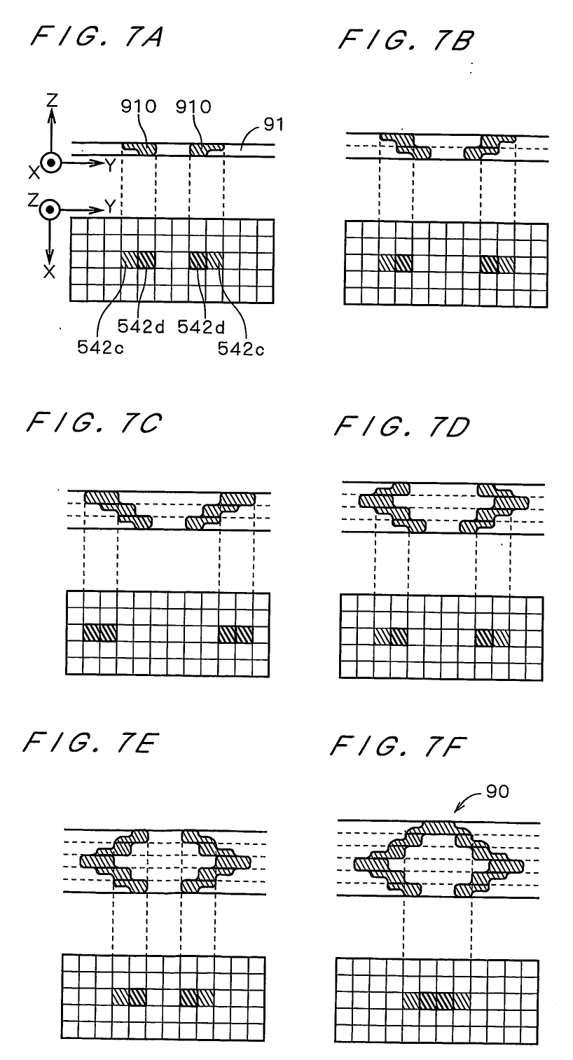

Hereafter, formation of microstructures for probe by the photo-fabrication apparatus 1 will be discussed, and discussion will be made, first, on an operation without gray-scale control of the DMD 54, referring to FIGS. 4, 5A to 5D and 6A to 6F, and subsequently on an operation with gray-scale control, referring to FIGS. 4 and 7A to 7F.

FIG. 4 is a flowchart showing an operation flow where the photo-fabrication apparatus 1 forms microstructures for probe. On the main surface of the base board 9, a lot of electrode pads are formed by photolithography or the like at microscopic intervals in a very small range in advance and microstructures for probe are formed on the electrode pads by the photo-fabrication apparatus 1.

In formation of the microstructures, first, data (hereinafter, referred to as “cross-sectional data”) 811 indicating a cross-sectional shape in a case of slicing a lot of three-dimensional microstructures to be formed by a given thickness (hereinafter, referred to as “slice width”) in a direction of height (the Z direction of FIG. 1) is separately generated in advance from three-dimensional information (i.e., shape data) such as CAD data, and the photo-fabrication apparatus 1 receives the cross-sectional data 811 and stores it into the storage part 81 of the control part 8 (Step S11). The cross-sectional data 811 may be generated by the operation part 82 on the basis of three-dimensional information of microstructure. Further, from the cross-sectional data of one microstructure, cross-sectional data collecting a lot of the same microstructures may be generated.

Subsequently, the camera 58, receiving a signal from the control part 8, picks up an image of an alignment mark on the base board 9 and transmits image data to the control part 8. The control part 8 detects a position of the base board 9 relative to the objective lens 57 (in other words, a distance between a reference position on the base board 9 and the objective lens 57 in the X and Y directions) on the basis of the image data and controls the stage moving mechanism 6 to move the base board 9 to a predetermined position on the basis of the detected result (Step S12).

Further, the control part 8 detects a spacing between the squeegee 41 and the base board 9 (in other words, a distance between a lower edge of the squeegee 41 and the main surface of the base board 9, and hereinafter referred to as a “squeegee gap”) on the basis of information on focusing at the time when the camera 58 acquires the image data and controls the stage up-and-down moving mechanism 7 to adjust the squeegee gap to be the slice width on the basis of the detected result and information on the slice width which is included in the cross-sectional data 811 (Step S113).

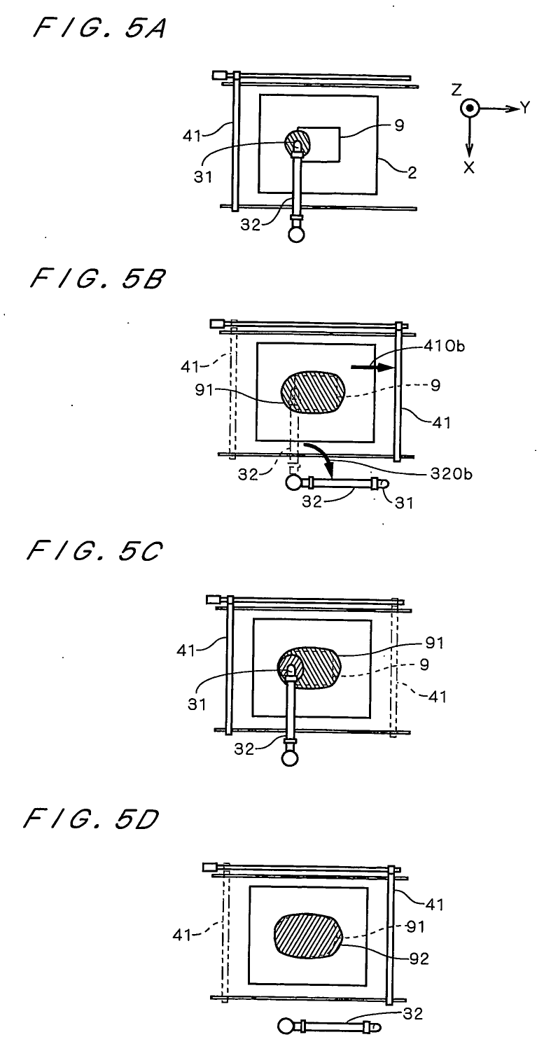

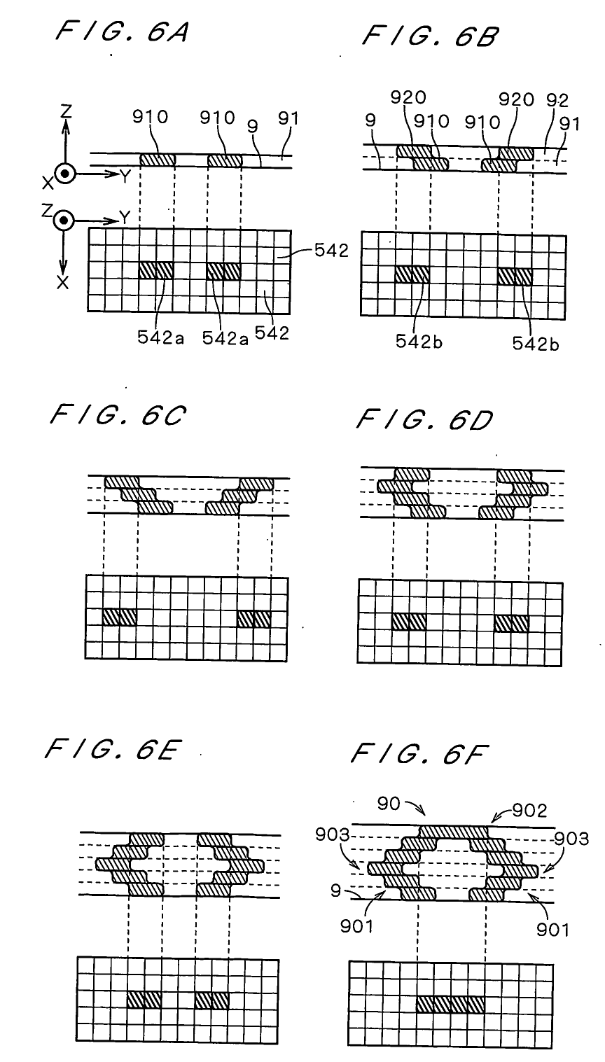

FIGS. 5A to 5D are views showing formation of a layer(s) of photosensitive material (hereinafter, referred to as a “material layer”), where the photosensitive material is fed onto the base board 9 and smoothly spread by the squeegee 41, and FIGS. 6A to 6F are views showing steps of sequentially piling up the material layers on the base board 9, with attention focused on one microstructure for probe. In each of FIGS. 6A to 6F, an upper view shows a cross section of material layers to be piled up and a lower one is a plan view of the material layers.

When adjustment of the squeegee gap (Step S13) is completed, first, the arm 32 rotates to move the nozzle 31 above the base board 9 as shown in FIG. 5A. At that time, the nozzle 31 is disposed above an edge of the base board 9 on the (−Y) side (in other words, on a side near an initial position of the squeegee 41 shown in FIG. 5A). Subsequently, with control of the control part 8, the valves 312 and 315 are temporarily opened and the pump 313 accurately drops a predetermined amount of the photosensitive material from the material tank 316 through the nozzle 31 onto the base board 9 (Step S14). In FIG. 5A (and 5B to 5D), the photosensitive material on the base board 9 is hatched.

Next, as shown in FIG. 5B, with rotation of the arm 32, as indicated by an arrow 320b from a position indicated by the two-dot chain line, the nozzle 31 pulls off outside the base board 9 and the squeegee 41 moves from the initial position indicated by the two-dot chain line along the main surface of the base board 9 in a direction indicated by an arrow 410b.

Since the photosensitive material fed onto the base board 9 has high viscosity and mounted on the base board 9 higher than the squeegee gap, when the squeegee 41 moves in the Y direction along the main surface of the base board 9 with a spacing between the lower edge thereof and the main surface of the base board 9 kept constant, the photosensitive material is smoothly spread (i.e., squeegeed) on the base board 9 to have a thickness equal to the squeegee gap and a first material layer 91 of photosensitive material is thereby formed on the base board 9 as shown in FIG. 5B (Step S15). At that time, redundant photosensitive material is pushed (or squeezed) out into a region outside the base board 9 (specifically, on the stage 2).

When formation of the first material layer 91 is completed, next, the control part 8 controls the light source 51 to start emission of light beam and controls the DMD 54 (Step S16), to thereby emit the light beam onto the material layer 91. Specifically, the control part 8 writes cell data into memory cells corresponding to the micromirrors 541 in the DMD 54, and when the control part 8 transmits a reset pulse to the DMD 54, the micromirrors 541 take orientations in accordance with the data in the corresponding memory cells, and the light beam emitted from the light source 51 are thereby spatially modulated by the DMD 54 and thus emission of light to the microscopic regions 542 is controlled.

The light from the light emitting part 5 is thereby emitted, as shown in the lower view of FIG. 6A, to specific microscopic regions 542a (the hatched regions) among the microscopic regions 542 on the base board 9, which is determined in advance on the basis of the cross-sectional data 811, and after light emission for a predetermined time period, the shutter 53 is closed to stop emission of the light beam from the light source 51 (Step S17). As a result, part of the material layer 91 is hardened to form two resin blocks 910, as indicated by hatching in the upper view of FIG. 6A. The resin blocks 910 exist in the material layer 91, being hardened by light emission and appear as blocks after unhardened material is removed in the later step (the same applies to other resin blocks discussed later).

When a range where the microstructures are formed is wider than a range of light emission by the DMD 54, the stage moving mechanism 6 of FIG. 1 is driven to move the light emission range and then light emission is repeated. Though the above discussion is made, assuming that the nozzle 31 moves, the nozzle 31 may be fixed above the base board 9 if the level of the squeegee 41 is sufficiently low and no problem arises even if the photosensitive material is dropped from a position higher than the squeegee 41 and further the arm 32 does not block the light emission from the light emitting part 5 to the material layer 91.

When formation of the resin blocks in accordance with one cross-sectional data 811 is completed, the control part 8 checks if formation of the whole microstructures is completed and then the operation flow goes back to Step S13 where the adjustment of squeegee gap is performed (Step S18) and formation of the second material layer is started.

In formation of the second resin block 910 from the base board 9, first, the stage up-and-down moving mechanism 7 is driven to move the stage 2 downward by the slice width so that the squeegee gap should be made twice as large as the slice width (Step S13). A distance between the lower edge of the squeegee 41 and a surface of the first material layer 91 thereby becomes equal to the slice width.

Next, as shown in FIG. 5C, the squeegee 41 is moved to the initial position, the arm 32 rotates to move the nozzle 31 above the base board 9 and the photosensitive material is fed from the nozzle 31 onto the base board 9 (Step S14). In FIG. 5C, a photosensitive material which is fed this time is hatched differently from the first material layer 91. After that, as shown in FIG. 5D, as the squeegee 41 moves, the second material layer 92 having a thickness equal to the slice width is formed on the existing material layer 91 and redundant photosensitive material is pushed out into a region outside the material layer 91 (Step S15).

When formation of the second material layer 92 is completed, light from the light emitting part 5 is emitted to specific microscopic regions 542b (hatched regions in the lower view of FIG. 6B) on the basis of the cross-sectional data 811 on the material layer 92 and the second resin blocks 920 are formed on the first resin blocks 910 as indicated by hatching in the upper view of FIG. 6B. Since the light emitted to a surface of the second material layer 92 is shielded to some degree by a boundary between the material layer 91 and the material layer 92 and hardly reaches the first material layer 91, it has no effect on a hardened state of the existing material layer.

Then, operations of increasing the squeegee gap by slice width to form the material layer and emitting the spatially-modulated light beam (Steps S13 to S17) are repeated at required times (Step S18), and as shown in FIGS. 6C to 6F, the material layers are piled up and new resin blocks are sequentially piled up on the existing resin blocks, to thereby form microstructures 90 for probe on the base board 9.

In formation of a new material layer on the base board 9 or the existing material layer, it is proved that a thickness of the material layer can be 20 μm or less when the viscosity of the photosensitive material is set 1500 cP (centipoise) or more (preferably, about 2000 cP). A height of the microstructure 90 for probe is 2 mm or less at the maximum from the main surface of the base board 9. Since the material layer is formed on a microscopic region, no bath for storing the photosensitive material is needed in the photo-fabrication apparatus 1 as discussed above and the material layer can be stably formed only if the redundant photosensitive material is pushed out into a region outside the existing material layer through movement of the squeegee 41.

As shown in FIG. 6F, the microstructure 90 for probe has an arch structure having two protruding parts 901 protruding from two portions on the base board 9 and a connecting part 902 (a portion near an upper end of the microstructure 90) for connecting tips of the two protruding parts 901 (upper ends of portions roughly regarded as the protruding parts 901) and is stably formed on the base board 9.

The two protruding parts 901 protrude so that near the base board 9, the tips thereof should become apart from each other as the distance from the base board 9 becomes larger, and the width of the microstructure 90 gets to the maximum at a position away from the base board 9 to some degree. For this reason, when the tip of the microstructure 90 after removal of the unnecessary photosensitive material in the later process receives a force toward the base board 9, the microstructure 90 bends with portions at the maximum width and around it serving as flexible parts 903 which are distorted with respect to a direction orthogonal to the base board 9 and the tip can easily move toward the base board 9. Since the microstructure 90 has such an elastic structure (a structure with spring properties), it is possible to establish an excellent contact between the probes and an electric circuit on a semiconductor substrate in an electrical inspection for the electric circuit discussed later. It is preferably that a spring constant of the microstructure 90 should be about 10² to 10⁵ N/m for excellent contact between the probes and the electric circuit.

Next, discussion will be made on an operation of the photo-fabrication apparatus 1 in the case where the gray-scale control of the DMD 54 is performed. When the gray-scale control is performed, in the photo-fabrication apparatus 1, a conversion table 812 indicating the quantity of light to be emitted to one microscopic region 542 on the material layer and a height of a remaining resin block (a depth of exposure) after removal of the unnecessary photosensitive material is produced in advance and stored in the storage part 81 (see FIG. 1).

The cross-sectional data in the case of not performing the gray-scale control for the DMD 54, which is inputted to the control part 8 in Step S11 of FIG. 4, is binary data indicating whether light should be emitted or not for each microscopic region 542, in other words, whether a resin block should be formed in the microscopic region 542 while the cross-sectional data in the case of performing the gray-scale control for the DMD 54 has not only information on whether a resin block should be formed in the microscopic region 542 but also information indicating the thickness of microscopic block (exactly, the thickness from an upper surface of the material layer or the thickness from a lower surface of the material layer). Hereinafter, such data is referred to as “extended cross-sectional data”.

In the photo-fabrication apparatus 1, on the basis of the extended cross-sectional data, not only whether light emission to each microscopic region 542 on each material layer should be performed or not but also the quantity of light to be emitted are controlled. Specifically, on the basis of the extended cross-sectional data and the conversion table 812, the quantity of light to be emitted to each microscopic region 542 on each of the material layers is obtained by the operation part 82 and the cell data corresponding to each of reset pulses generated during a given time period is generated so that the quantity of light to be emitted should signify cumulative time of light emission.

Subsequently, like in the case of not performing the gray-scale control, adjustment of a position of the base board 9 relative to the objective lens 57 is performed (Step S12), and adjustment of the squeegee gap is performed (Step S13). Then, the photosensitive material is fed onto the base board 9 (Step S14), and the squeegee 41 smoothly spreads the photosensitive material on the base board 9 to form a material layer (Step S15).

When formation of the material layer is completed, the control part 8 controls the light source 51 to start emission of light beam and controls the DMD 54 (Step S16), to thereby start emission of the light subjected to the gray-scale control. In other words, write of the cell data and transmission of the reset pulse to the memory cell corresponding to each micromirror 541 in the DMD 54 from the control part 8 are repeated at high speed and the quantity of light to be emitted to each microscopic region 542 is accurately controlled.

When a predetermined number of transmissions of the reset pulses are finished, emission of the light beam from the light source 51 is stopped (Step S17), and formation of resin blocks in accordance with the extended cross-sectional data for one layer is completed. After that, like in the case of not performing the gray-scale control, the control part 8 checks if formation of the whole microstructure is completed (Step S18), and if not completed, adjustment of the squeegee gap (Step S13), feeding of the photosensitive material (Step S14), formation of the material layer (Step S15) and light emission (Steps S16 and S17) are repeated. When formation of all the resin blocks is completed, the repeating operation is finished (Step S18).

FIGS. 7A to 7F are views showing formation of a microstructure 90 in the case where the light from the light emitting part 5 is subjected to the gray-scale control, and in each figure, an upper view shows resin blocks in material layers and a lower view shows light emission. Hatched regions in the lower view of FIG. 7A are microscopic regions on the first material layer 91 to which light is emitted, and with control for the DMD 54, the time for light emission to microscopic regions 542c which are hatched with thin lines is made shorter than that to microscopic regions 542d which are hatched with thick lines (in other words, the cumulative quantity of light emitted thereon is made smaller).

With this gray-scale control, as shown in the upper view of FIG. 7A, in the first resin blocks 910, portions corresponding to the microscopic regions 542c are thinner than portions corresponding to the microscopic regions 542d, and as shown in FIGS. 7B to 7F, by piling up the resin blocks while performing gray-scale control of light, a microstructure 90 having a smooth shape (see FIG. 7F) is formed, as compared with that in the case without the gray-scale control. As a result, a microstructure 90 having a stable spring constant is obtained, and as discussed later, with a probe manufactured from the microstructure 90, it is possible to more reliably establish contact between the probes and an electric circuit in an electrical inspection for the electric circuit.

Actually, however, it is considered that the smoother shape of the microstructure is obtained not because a hardened portion of photosensitive material becomes thinner by the gray-scale control but in removal of unhardened photosensitive material in the later process, part of incomplete hardened portion and a sufficiently hardened portion are united, remaining, to be the smooth-shaped microstructure 90 as shown in FIG. 7F.

Through the above operations, in the photo-fabrication apparatus 1 of the first preferred embodiment, a plurality of microstructures 90 for fine probe, each consisting of a plurality of resin blocks which are piled up and having a predetermined three-dimensional shape, are stably formed on the electrode pads on the base board 9. Since the spatially-modulated light beam (i.e., a flux of many modulated light microbeams) is generated by the DMD 54 and emitted to the material layer at high speed with high positional accuracy, a lot of microstructures for probe can be formed and arranged at high speed with high positional accuracy.

Further, the photo-fabrication apparatus 1 does not need a resin bath, unlike a conventional and general photo-fabrication apparatus using light, since it adopts the technique to form microstructures in which the photosensitive material is fed directly onto the base board 9 and the photosensitive material unnecessary for formation of the material layer is pushed out into a region outside an existing material layer, and it is therefore possible to achieve size reduction of the photo-fabrication apparatus 1.

Since the base board 9 on which the microstructures 90 are formed in the material layers by the photo-fabrication apparatus 1 is cleared of the unhardened resin in the subsequent process (for example, the base board 9 is immersed in developer and the photosensitive material to which no light is emitted is solved therein and removed), it is possible to easily obtain a board for probe card comprising a lot of microstructures 90 each formed of resin blocks piled up on the main surface of the base board 9.

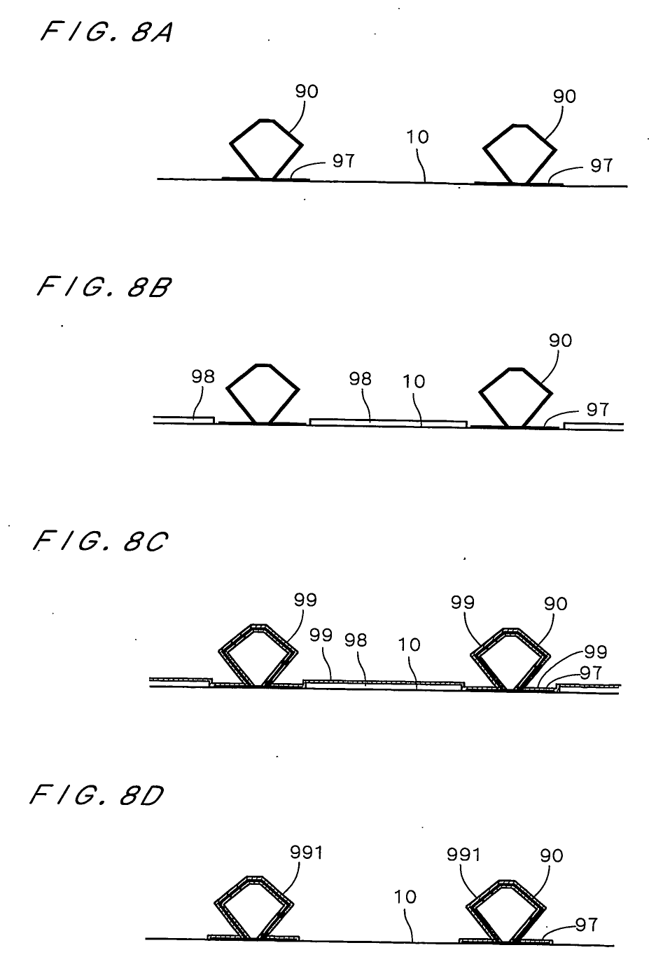

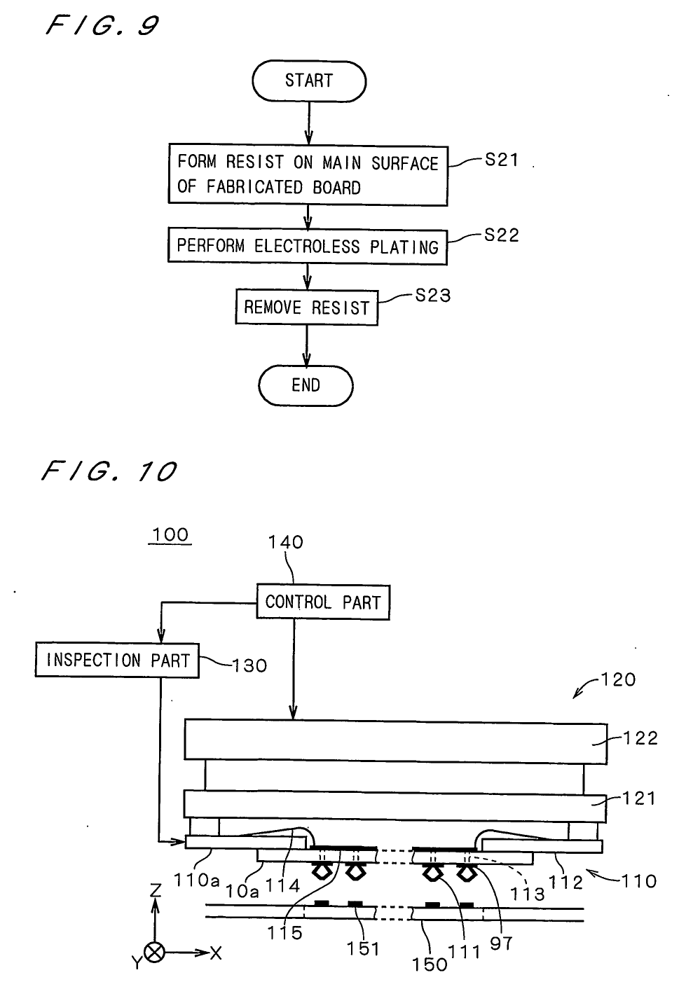

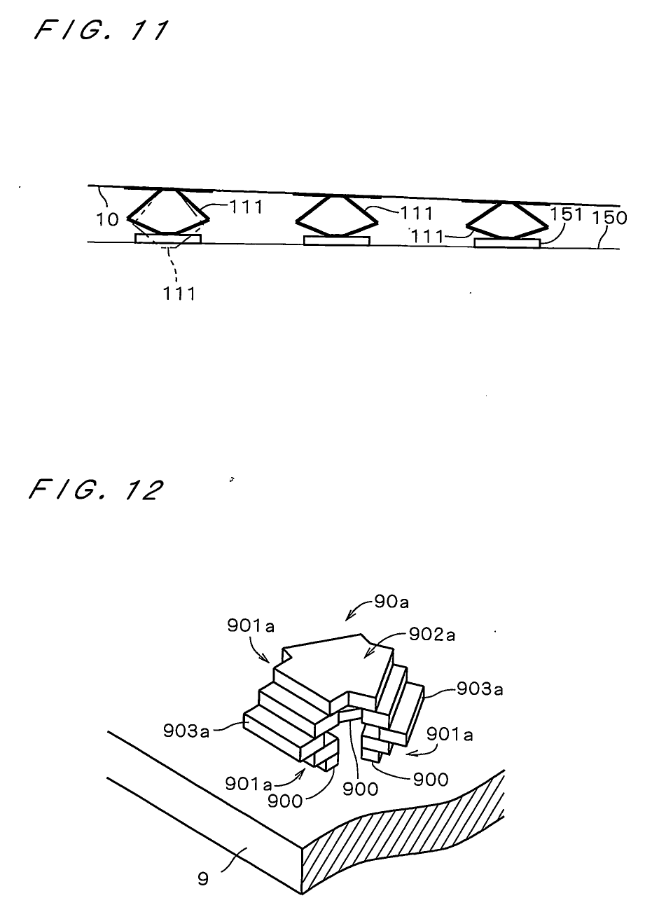

FIGS. 8A to 8D are views showing a plating operation for microstructures 90 on a board 10 for probe card to become probes, and FIG. 9 is a flowchart showing an operation flow of the plating. In the following discussion, the board 10 for probe card before plating is referred to as a “partially fabricated board 10”.

As shown in FIG. 8A, the electrode pads 97 are formed on a main surface of the partially fabricated board 10 (in other words, the surface of the base board 9 shown in FIG. 5A) as discussed above, and the microstructures 90 are further formed thereon. In the process step of plating, first, as shown in FIG. 8B, a resist 98 is formed in a portion on the main surface of the partially fabricated board 10 where no electrode pad 97 is formed (Step S21). Next, the partially fabricated board 10 is immersed in a plating bath, being subjected to electroless plating, to form a coating film 99 of conductive nickel (which may be other metal such as copper) on surfaces of the microstructures 90, the electrode pads 97 and the resist 98 (Step S22).

When the plating is finished, as shown in FIG. 8D, an unnecessary coating film 99 is removed by peeling off the resist 98 from the partially fabricated board 10 (Step S23). Through these operations, a board for probe card (hereinafter, referred to as a “metal-plated board”) having coating films (hereinafter, referred to as “conductive films”) 991 each of which continuously coats a microstructure 90 and an electrode pad 97 is completely achieved.

A probe card is manufactured by bonding the metal-plated board to electrodes of a main board which is separately prepared through wire-bonding. The bonding of the metal-plated board to the main board may be performed by a method using bumps or the like.

FIG. 10 is a view showing an inspection apparatus 100 for inspecting electric circuits 151 on a semiconductor substrate 150 by using the probe card manufactured through the above operations. The inspection apparatus 100 comprises a probe card 110 having probes 111 where conductive films are formed, respectively, a probe head 120 for pressing the probes 111 of the probe card 110 against a electric circuit (or electric circuits) 151, an inspection part 130 for electrically inspecting the electric circuit 151 through the conductive films of the probes 111 and a control part 140 for controlling the probe head 120 and the inspection part 130.

As discussed above, a metal-plated board 10a is attached to a main board 112 in the probe card 110 and the probe card 110 is attached to the probe head 120 so that the probes 111 on the metal-plated board 10a face a side of the semiconductor substrate 150 (the (−Z) side of FIG. 10). The probes 111 are arranged correspondingly to the electrode pads of the electric circuit 151, and the electrode pads 97 on the metal-plated board 10a on which the probes 111 are formed are electrically connected to a conductive pattern 115 of an upper surface of the metal-plated board 10a through vias 113 and further electrically connected to the main board 112 through gold wires 114. The main board 112 is electrically connected to the inspection part 130.

The probe head 120 has a mount part 121 on which the probe card 110 is mounted and a pressing mechanism 122 for moving the mount part 121 in the Z direction of FIG. 10 to press the probes 111 against the electric circuit 151 to be inspected.

When the inspection apparatus 100 inspects one electric circuit 151, first, a predetermined electric circuit(s) 151 on the semiconductor substrate 150 is moved directly below the probe card 110 and with control by the control part 140, the pressing mechanism 122 moves the probe card 110 downward to press the probes 111 against the electric circuit 151.

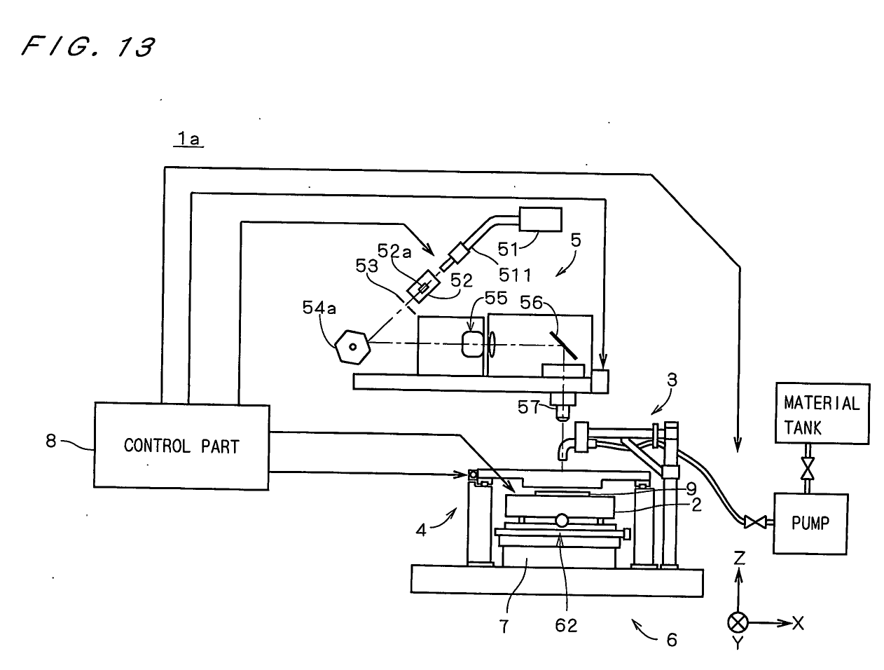

FIG. 11 is an enlarged view showing a state where the probes 111 are pressed against the electric circuit 151 and deformed. In FIG. 11, the probe 111 before being deformed is also indicated by a two-dot chain line. Since the probes 111 can be elastically deformed as discussed above, they are easily bent when pressed against the electric circuit 151 and even a small pressing force allows a reliable contact between all the probes 111 and the electric circuit 151. In particular, even if the probe card is slightly inclined with respect to the semiconductor substrate 150 (in other words, even if there is an error in relatively-positional relation in a vertical direction between the probes 111 and the electric circuits 151) as shown in FIG. 11, tips of the probes 111 are brought into contact with the electric circuit 151 through elastic deformation by a pressing force (contact force) within a proper range.

When the probe card 110 comes into contact with the electric circuit 151, an electrical signal for inspection is outputted from the inspection part 130, the inspection signal is inputted to (the electrode pads 97 of) the electric circuit 151 through the corresponding probes 111 and output signals from other electrode pads 97 are inputted to the inspection part 130 through the probes 111 for detection. In a case of inspection only on conductivity of a predetermined portion of the electric circuit 151, input and detection of signals are performed with two probes 111 made a pair. In a case of advanced inspection, inspection signals from a plurality of probes 111 are inputted and an output signal from the electric circuit 151 is detected by at least one other probe 111. Then, the inspection part 130 judges pass/fail of the electric circuit 151 on the basis of the detected signal.

In a semiconductor substrate, generally, the electrode pads through which the electric circuit 151 and the probes 111 are in contact with each other are formed of aluminum (Al) and their surfaces are apt to be covered with insulative oxide films. The inspection apparatus 100 achieves an excellent continuity between the probes 111 and the electric circuit 151 with high voltage across the probes 111 and the electrode pads to ensure dielectric breakdown of the oxide films on the electrode pads. Conventionally, a technique of slightly scraping off the oxide film on the surface of the electrode pad with the probe itself to establish continuity between the probe and the electrode pad has been adopted. On the other hand, in the inspection apparatus 100, since such a technique is not adopted and therefore no chip of the oxide film is deposited on the tips of the probes 111, it is possible to reduce works for maintenance of the probes 111 and achieve improvement of inspection efficiency.

Thus, in the inspection apparatus 100, with the probe card 110 using the microstructures formed by the photo-fabrication apparatus 1, it is possible to surely establish contact between the probes 111 and the electric circuit 151. Especially, since the photo-fabrication apparatus 1 allows a lot of microstructures for fine probe to be arranged in a microscopic area with high positional accuracy, the probe card 110 is suitable for electrical inspection of electric circuits on semiconductor substrates (semiconductor chips).

FIG. 12 is a perspective view showing another example of microstructure for probe formed on the base board 9. A microstructure 90a protrudes from three portions positioned nonlinearly on the base board 9 (in other words, three portions regarded as vertices of a triangle on the base board 9, all of which are represented by reference numeral 900 in FIG. 12) so that protruding parts 901a are away from one another, and tips of the three protruding parts 901a are connected by a connecting part 902a which is positioned near a tip of the microstructure 90a.

With such a construction, in the microstructure 90a, portions at the largest width (horizontally protruding portion) serve flexible parts 903a which is easily elastically deformed and a portion farthest away from the base board 9 can be easily moved toward the base board 9. As a result, a probe manufactured on the basis of the microstructure 90a, like the probe of FIG. 11, can establish a reliable contact with an electric circuit to be inspected with a small pressing force with high positional accuracy.

Since the protruding parts 901a are nonlinearly arranged, the probe resists being bent sideward even if it receives a force parallel to the base board 9. Further, in forming the microstructure 90a, the gray-scale control of the DMD 54 may be performed as discussed above.

FIG. 13 is a view showing a construction of a photo-fabrication apparatus 1a in accordance with the second preferred embodiment. In the photo-fabrication apparatus 1a, an acousto-optical modulator (hereinafter, abbreviated as “AOM”) 52a is added to the optical system 52 in the light emitting part 5 of FIG. 1 and a polygon mirror 54a which is rotated by a motor (not shown) is provided instead of the DMD 54. Other constituents of the light emitting part 5 and constituents in the photo-fabrication apparatus 1a other than the light emitting part 5 are the same those in the photo-fabrication apparatus 1 and represented by the same reference signs.

The light beam emitted from the light source 51 through the optical fiber bundle 511 is modulated by the AOM 52a and goes toward the polygon mirror 54a through the shutter 53. The light beam reflected on the rotating polygon mirror 54a is guided to the mirror 56 through the group of lenses 55. Further, the light beam reflected on the mirror 56 is guided onto the base board 9 through the objective lens 57.

The irradiation position (or microscopic region) of light is moved by the polygon mirror 54a in the main scan direction (the X direction of FIG. 13) and the base board 9 is moved by the Y-direction moving mechanism 62 in the Y direction of FIG. 13 to move the irradiation position in the subscan direction. The control part 8 controls the AOM 52a and the Y-direction moving mechanism 62 in synchronization with rotation of the polygon mirror 54a, to switch between ON and OFF of light emission to each microscopic region on the base board 9, and thus microstructures for probe are formed on the base board 9, like in the first preferred embodiment.

Further, the gray-scale control of light beam (control on light intensity in emission to one microscopic region) may be performed on the basis of the extended cross-sectional data discussed earlier.

Though the preferred embodiments of the present invention have been discussed above, the present invention is not limited to the above-discussed preferred embodiments, but allows various variations.

For example, there may be a construction where the squeegee 41 is fixed and the base board 9 held on the stage 2 is moved by the Y-direction moving mechanism 62 in the Y direction of FIG. 1 to smoothly spread the photosensitive material. The movement direction of the squeegee 41 relative to the base board 9 only has to be one along the main surface of the base board 9 and the orientation of the squeegee 41 is not necessarily orthogonal to the movement direction.

A collection mechanism may be additionally provided at a side of the stage 2 to collect the redundant photosensitive material which is pushed off into a region outside the existing material layer in the layer formation step.

The light emitting part 5 may be changed as appropriate only if it can form a microscopic light spot on the material layer. For example, a light beam which is spatially modulated by a liquid crystal shutter may be generated, or there may be case where multibeams (light beam subjected to one-dimensional spatial modulation) are generated by individually modulating divided laser beams and deflected by a polygon mirror or a galvanic mirror for scanning.

The conversion table 812 used in the gray-scale control is not necessarily a table directly indicating a relation between the quantity of light to be emitted to one microscopic region 542 and an exposure depth of the material layer (exactly, a thickness of a portion left after removal of the unnecessary photosensitive material) but only has to be a table substantially indicating the relation. For example, the conversion table 812 may be a table or function indicating a relation between a light emission time and an exposure depth, or a table indicating a relation between the number of ON states of the DMD 54 and an exposure depth.

In the photo-fabrication apparatus 1 of the first preferred embodiment, it is possible to perform the gray-scale control while continuously moving the irradiation region. Specifically, by controlling the stage moving mechanism 6 in synchronization with the control of the DMD 54 to transmit the reset pulse to the DMD 54 every time when the irradiation region moves by one microscopic region, the gray-scale control using the number of duplicate light emission can be performed. It is thereby possible to quickly emit light which is substantially subjected to the gray-scale control to a wide region on the material layer.

The shape of the microstructure for probe formed by the photo-fabrication apparatus is not limited to that shown in FIGS. 6F, 7F or 12, but any shape may be adopted only if the microstructure has a portion which can be regarded as a flexible part and with a bend of the flexible part, a portion of the microstructure farthest away from the base board 9 is moved toward the base board 9 to establish a reliable contact between a probe and an electric circuit to be inspected.

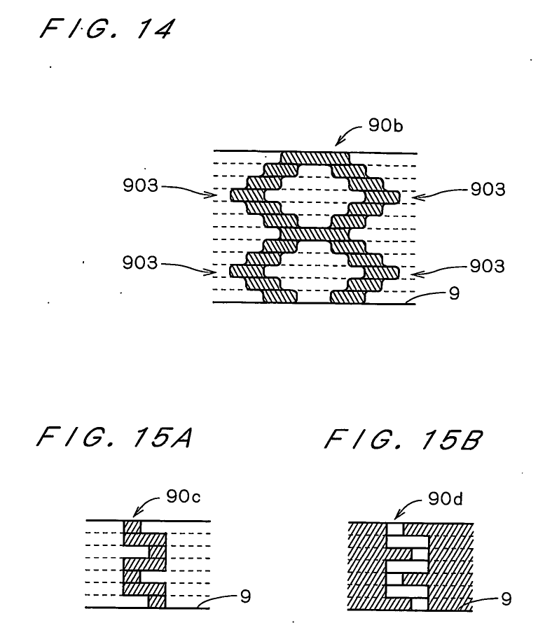

FIG. 14 is a view showing a microstructure 90b (hatched) in which the microstructures 90 of FIG. 6F are piled up in two stages. In the microstructure 90b, with the flexible parts 903 which are portions at the largest width and around it in the two, upper and lower stages, its tip can be moved toward the base board 9 even by a very weak force. Further, a microstructure 90c of substantial spring type as indicated by hatching in FIG. 15A may be used. In this case, portions extending approximately parallel to the base board 9 mainly serve as flexible parts.

The photosensitive material does not necessarily always have to be liquid but may be one which is solidified to some degree after being fed onto the base board 9 and partially subjected to light emission in development of the later process to be left on the base board 9. Further, the photosensitive material is not limited to a negative-type one such as a photocurable resin but may be a positive-type one which is partially subjected to light emission to be removed in development. FIG. 15B is a view showing a state where the microstructure 90d of substantial spring type shown in FIG. 15A is formed by using the positive-type photosensitive material, and a hatched portion in FIG. 15B is removed by light emission in development.

If flexibility is scarcely required of the probe, a bench-type microstructure may be formed in which the tips of the two protruding parts 901 orthogonal to the main surface of the base board 9 are connected by a connecting part parallel to the main surface of the base board 9.

While the invention has been shown and described in detail, the foregoing description is in all aspects illustrative and not restrictive. It is therefore understood that numerous modifications and variations can be devised without departing from the scope of the invention.

### INDUSTRIAL APPLICABILITY

The present invention can be used for a technique to manufacture a probe card for electrically inspecting fine electric circuits formed on semiconductor substrates (or semiconductor chips), glass substrates used for liquid crystal displays, printed circuit boards or the like, and an inspection apparatus comprising the probe card.

1. A board for probe card used for an electrical inspection of an electric circuit, comprising:
a base board; and
three-dimensional structures each having a plurality of blocks piled up on said base board, said plurality of blocks being formed of photosensitive material.

2. The board for probe card according to claim 1, wherein
each of said three-dimensional structures comprises a flexible part which bends to allow a portion farthest away from said base board to be moved toward said base board.

3. The board for probe card according to claim 1, wherein
each of said three-dimensional structures comprises:
a plurality of protruding parts which protrude from said base board; and
a connecting part for connecting tips of said plurality of protruding parts.

4. The board for probe card according to claim 3, wherein
said plurality of protruding parts protrude from three portions which are nonlinearly arranged on said base board.

5. The board for probe card according to claim 1, further comprising
a conductive film for coating each of said three-dimensional structures.

6. The board for probe card according to claim 5, wherein
said conductive film is a metal coating film formed by electroless plating.

7. An inspection apparatus for performing an electrical inspection of an electric circuit, comprising:
a probe card on which probes are provided;
a pressing mechanism for pressing said probes toward an electric circuit to be inspected; and
an inspection part for electrically inspecting said electric circuit through said probes,
wherein said probe card comprises
a base board;
three-dimensional structures each having a plurality of blocks formed of photosensitive material and piled up on said base board; and
conductive films for coating said three-dimensional structures, respectively.

8. A photo-fabrication apparatus for forming three-dimensional structures for probes used for an electrical inspection of an electric circuit;
a holding part for holding a base board;
a feeding part for feeding liquid photosensitive material onto said base board;
a squeegee for forming a layer of photosensitive material which is fed onto said base board on an existing layer and pushing redundant photosensitive material out into a region outside said existing layer through movement relative to said base board in a predetermined direction along a main surface of said base board;
a moving mechanism for moving said squeegee relatively to said base board in said predetermined direction;
a spacing change mechanism for changing a spacing between said squeegee and said holding part; and
a light emitting part for emitting light to a region which is determined in advance with respect to a layer of photosensitive material formed through movement of said squeegee.

9. The photo-fabrication apparatus according to claim 8, wherein
said layer of photosensitive material has a thickness of 20 μm or less.

10. The photo-fabrication apparatus according to claim 8, wherein
said light emitting part comprises a spatial light modulator for generating a spatially-modulated light beam.

11. The photo-fabrication apparatus according to claim 8, further comprising
a control part for controlling the quantity of light to be emitted to each microscopic region on a layer of photosensitive material.

12. The photo-fabrication apparatus according to claim 11, wherein
said control part comprises:
a storage part for storing shape data of a three-dimensional structure formed on a board and a table substantially indicating a relation between the quantity of light to be emitted onto a microscopic region on a layer of photosensitive material and a depth of exposure of said layer; and
an operation part for obtaining the quantity of light to be emitted for each microscopic region on each layer of photosensitive material piled up to form said three-dimensional structure on the basis of said shape data and said table.

13. A photo-fabrication method for forming three-dimensional structures for probes used for an electrical inspection of an electric circuit, comprising:
a feeding step for feeding liquid photosensitive material onto a base board;
a layer formation step for forming a layer of said photosensitive material on said base board by moving a squeegee relatively to said base board in a predetermined direction along a main surface of said base board;
a light emitting step for emitting light to a region which is determined in advance with respect to said layer of photosensitive material; and
a repeating step for repeating said feeding step, said layer formation step and said light emitting step a plurality of times, wherein
said layer of photosensitive material is formed on an existing layer and redundant photosensitive material is pushed out into a region outside said existing layer in said layer formation step included in said repeating step.
